(19) United States
(12) Patent Application Publication
(10) Pub. No.: US 2021/0269909 A1
(43) Pub. Date: Sep. 2, 2021

(54) ARTICLE/PART COMPRISING A POLYMERIC COMPONENT AND A METALLIC COATING

(71) Applicant: SOLVAY SPECIALTY POLYMERS USA, LLC, Alpharetta, GA (US)

(72) Inventors: Vijay GOPALAKRISHNAN, Dunwoody, GA (US); Imani B. JONES, Alpharetta, GA (US); Mohammad Jamal EL-HIBRI, Atlanta, GA (US); Keshav S. GAUTAM, Suwanee, GA (US)

(21) Appl. No.: 17/258,474

(22) PCT Filed: Jul. 9, 2019
(86) PCT No.: PCT/EP2019/068463

§ 371 Date: Jan. 7, 2021

Related U.S. Application Data
(60) Provisional application No. 62/697,570, filed on Jul. 13, 2018.

(30) Foreign Application Priority Data
Aug. 17, 2018 (EP) 18189544.2

(51) Int. Cl. C23C 14/20; C08L 71/00; C08L 81/06; C23C 14/02; C23C 14/58

(52) U.S. Cl. CPC C23C 14/20; C08L 71/00; C23C 14/5853; C23C 14/021; C08L 81/06

(57) ABSTRACT

The invention pertains to a article or a part, comprising: —a first layer (1) of a composition (C) comprising a polymeric component comprising a) at least one poly(aryl ether ketone) polymer (PAEK), and b) at least one poly(aryl ether sulfone) polymer (PAES), wherein the composition (C) further comprises glass fibers and/or carbon fibers and has a melting temperature (Tm) of at least 290° C., as measured by differential scanning calorimetry (DSC) according to ASTM D3418, and—at least one coating (2) of metal having a thickness of at least 20 μm, preferably at least 30 μm. The present invention also relates to a process for preparing this article/part by metallisation and to the use of such articles and parts in electrical & electronic applications, mobile electronics, smart devices & wearables and smart phones.

### RELATED APPLICATIONS

This application claims priority to U.S. Provisional App No. 62/697,570 filed on Jul. 13, 2018 and to European patent application No. 18189544.2 filed on Aug. 17, 2018, the whole content of each of these applications being incorporated herein by reference for all purposes.

### TECHNICAL FIELD

The present disclosure relates to a article or a part, comprising:
a first layer (1) of a composition (C) comprising a polymeric component comprising a) at least one poly(aryl ether ketone) polymer (PAEK), and b) at least one poly(aryl ether sulfone) polymer (PAES), wherein the composition (C) further comprises glass fibers and/or carbon fibers and has a melting temperature (Tm) of at least 290° C., as measured by differential scanning calorimetry (DSC) according to ASTM D3418, and
at least one coating (2) of metal having a thickness of at least 30 μm, preferably at least 40 μm.

The present invention also relates to a process for preparing this article/part by metallisation and to the use of such articles and parts in electrical & electronic applications, mobile electronics, smart devices & wearables and smart phones.

### BACKGROUND ART

There is a high demand for the production of metallic coatings in various industrial sectors, from simple operations such aesthetic layers to more complex applications like electronic devices. Coatings of various types are frequently applied on parts to protect against hostile environments, to enhance their performance and durability, but also for aesthetic reasons. When considering the manufacturing of metallic coatings on surfaces, thermal spray methods are widely used for industrial applications. In such processes, the feedstock metal, typically in the form of powder or wire, is heated to melting point and propelled as individual droplets towards the working surface. The energy required for the melting process is usually generated by combustible gases or an electric arc. As the particles impinge on the substrate, they splat (deform) and solidify.

Physical Vapor Deposition (PVD) is one of the available metallization methods. High temperature PVD is a cost effective way of shielding articles or parts, for examples with unique geometries. PVD metallization process also offers the advantages of a high throughtput and a metal coating of a significant thickness.

Due to their cost and ease of processing/shaping, polymeric materials are widely used. They however present a certain number of weaknesses for certain industries, for example erosion, swelling, warpage, porosity and susceptibility to certain fluids. Applying metal coatings or layers to the surface of polymer articles/parts is of considerable commercial importance because of the desirable properties obtained by combining polymers and metals.

Several prior art documents describe polymer-metal hydrib articles and methods for obtaining these articles.

U.S. Pat. No. 9,909,207 describes a process for the deposition of aluminum on to non-metallic and composite substrates, such as polyether ether ketone (PEEK) or polyether ketone ketone (PEKK), wherein the non-metallic and composite substrates have opposing first and second sides. The substrate is inserted into a stream of ions and vapor of the coating with a first side of the substrate facing a first electric grid. The substrate is at the same voltage potential as the first electric grid and a primer coating is deposited on the first side. The primer coated first side is next coated to a desired thickness by insertion into the ion stream with the substrate at a negative potential relative to the first grid. The substrate is then rotated so the second side is facing the first grid with the substrate at a negative potential relative the first grid for a time effective to deposit the coating to a desired thickness.

US 2012/0237789 relates to metal-clad polymer article comprising a polymeric material defining a substrate and a metallic material covering at least part of a surface of said polymeric material, said metallic material having a microstructure and presenting a thickness between 10 and 500 microns. The article may comprise an intermediate layer between said polymeric material and said metallic material. The polymeric material may be epoxy resins, phenolic resins, polyester resins, urea resins, melamine resins, thermoplastic polymers, polyolefins, polyethylenes, polypropylenes, polyamides, poly-ether-ether-ketones, poly-aryl-ether-ketones, poly ether ketones, poly-ether-ketone-ketones, mineral filled polyamide resin composites, polyphthalamide, polyphtalates, polystyrene, polysulfone, polyimides, neoprenes, polyisoprenes, polybutadienes, polyisoprenes, polyurethanes, butadiene-styrene copolymers, chlorinated polymers, polyvinyl chloride, fluorinated polymers, polytetrafluoroethylene, polycarbonates, polyesters, liquid crystal polymers, partially crystalline aromatic polyesters based on p-hydroxybenzoic acid, polycarbonates, acrylonitrile-butadiene-styrene their copolymers and their blends.

U.S. Pat. No. 6,074,740 relates to a metallized plastics part based on a multiphase polymer mixture comprising a thermoplastic polymer A having a melting point of more than 100° C. and a polymeric filler B that promotes adhesion of a metal coat to the polymer mixture, and wherein the polymeric filler is at least one selected from the group consisting of polyarylene sulfide, oxidized polyarylene sulfide, polyimide, aromatic polyester and polyether ketone and a metal coat adhered to the polymer mixture.

One of the fundamental limitations associated with the PVD process is the lack of available polymer materials which can wistand the temperature used in the PVD process, generally above 250° C.

Poly(aryl ether ketone) polymers (PAEK) are a class of polymers that can be subjected to high temperatures for the duration of the PVD process without suffering degradation. However, the Applicant has notificed that PAEK polymers can suffer from other processing issues such as warpage which impacts the dimensional stability of the molded part.

There is therefore a need for polymeric part material to be used in high temperature metallization processes, which makes possible the manufacture of metal-coated polymeric articles/parts with an improved set of mechanical and aesthetic properties, notably with improved dimensional

### SUMMARY OF INVENTION

An aspect of the present disclosure is directed to an article or a part, comprising:
a first layer (1) of a composition (C) comprising a polymeric component comprising:
   a) at least one poly(aryl ether ketone) polymer (PAEK), and
   b) at least one poly(aryl ether sulfone) polymer (PAES), wherein the composition (C) further comprises glass fibers and/or carbon fibers and has a melting temperature (Tm) of at least 290° C., as measured by differential scanning calorimetry (DSC) according to ASTM D3418, and
at least one coating (2) of metal having a thickness of at least 20 μm, preferably at least 30 μm, and more preferably at least 40 μm.

The applicant has found that the combination of a PAES polymer and a PAEK polymer, is advantageous as the base of an article or part to be metallized by a process using high temperatures, e.g. above 250° C., for example PVD.

Another aspect of the invention is a process for preparing the article/part of the invention, by metallisation of an article/part comprising a first layer of a composition (C) which comprises a polymeric component comprising at least one poly(aryl ether ketone) polymer (PAEK) and at at least one poly(aryl ether sulfone) polymer (PAES), wherein the composition (C) has a melting temperature (Tm) of at least 290° C., as measured by differential scanning calorimetry (DSC) according to ASTM D3418. The metallisation may be performed by physical vapor deposition (PVD) in a high vaccum environment using thermal evaporation equipment. The article/part may be:
etched using a chemical solution before metal deposition,
polished before or after metal deposition,
colored before or after metal deposition, and/or
anodized after metal deposition.

Another aspect of the invention is the use of the article/part of the invention, for electrical & electronic applications, mobile electronics, smart devices & wearables and smart phones.

### DESCRIPTION OF EMBODIMENTS

The present invention relates to an article or a part, comprising:
a first layer (1) of a composition (C) comprising a polymeric component comprising:
   a) at least one poly(aryl ether ketone) polymer (PAEK),
   b) at least one poly(aryl ether sulfone) polymer (PAES),
   wherein the composition (C) further comprises glass fibers and/or carbon fibers and has a melting temperature (Tm) of at least 290° C., as measured by differential scanning calorimetry (DSC) according to ASTM D3418, and
at least one coating (2) of metal having a thickness of at least 20 μm, preferably at least 30 μm, and more preferably at least 40 μm.

The merit of the applicant has been to identify a composition of matter, also called hereby composition (C), which can wistand the high temperatures, for example above 250° C., used in metallization processes, such as PVD, and makes possible the manufacture of metallized articles or parts with improved dimensional stability.

The composition is such that it comprises a) at least one poly(aryl ether ketone) polymer (PAEK), and b) at least one poly(aryl ether sulfone) polymer (PAES), and that it has a melting temperature (Tm) of at least 290° C., as measured by differential scanning calorimetry (DSC) according to ASTM D3418.

The present invention is in fact based on the polymer combination of at least one PAES and at least one PAEK as the main element of the composition (C), to build the first layer of the metallized article or part. This composition presents a high melting temperature (Tm), at least 290° C., as measured by differential scanning calorimetry (DSC) according to ASTM D3418, for example at least 300° C. or at least 310° C.

Composition (C)

The composition (C) of the present invention constitutes the first layer (1) of the article or part, to be metallized with a layer of metal. The composition (C) is such that it comprises a) at least one poly(aryl ether ketone) polymer (PAEK), and b) at least one poly(aryl ether sulfone) polymer (PAES), and that it has a melting temperature (Tm) of at least 290° C., as measured by differential scanning calorimetry (DSC) according to ASTM D3418. The composition (C) also comprises glass fibers and/or carbon fibers.

The thickness of the first layer (1) may range from 100 μm to 5 cm, for example from 500 μm to 3 cm or from 1 mm to 1 cm.

The composition (C) comprises a polymeric component and glass fibers and/or carbon fibers, and may also comprise at least another component. The composition (C) may also comprise several additional components, for example glass fibers and additive(s).

The polymeric component of the composition (C) comprises at least one PAEK and at least one PAES. It may also comprise additional polymers, for example selected from the group consisting of polyimides and polyamides.

The polymeric component of the composition (C) may comprise:

a) from 55 to 95 wt. % of at least one poly(aryl ether ketone) (PAEK), and

b) from 5 to 45 wt. % of at least one poly(aryl ether sulfone) (PAES), based on the total weight of the polymeric component of the composition (C).

As explained above, the composition (C) of the invention may include other components. The composition (C) may for example comprise at least one additional component, for example selected from the group consisting of fillers, colorants, lubricants, plasticizers, stabilizers, flame retardants, nucleating agents and combinations thereof. Fillers in this context can be reinforcing or non-reinforcing in nature.

Suitable fillers include calcium carbonate, magnesium carbonate, glass fibers, graphite, carbon black, carbon fibers, carbon nanofibers, graphene, graphene oxide, fullerenes, talc, wollastonite, mica, alumina, silica, titanium dioxide, kaolin, silicon carbide, zirconium tungstate, boron nitride and combinations thereof.

In embodiments that include fillers the concentration of the fillers in the part material ranges from 0.5 wt. % to 50 wt. %, with respect to the total weight of the composition (C). In these embodiments, the composition (C) may comprise, based on the total weight of the composition (C):
from 0.5 wt. % to 50 wt. %, of glass fibers and/or carbon fibers, for example glass fibers, for example from 1 to 40 wt. %, from 2 to 30 wt. % or from 5 to 20 wt. %; and
from 50 to 99.5 wt. % of the polymeric component, as defined above, for example from 60 to 99 wt. %, from 70 to 98 wt. % or from 80 to 95 wt. %.

Glass fibers are silica-based glass compounds that contain several metal oxides which can be tailored to create different types of glass. The main oxide is silica in the form of silica sand; other oxides, such as oxides of calcium, sodium and aluminium, are incorporated to reduce the melting temperature and impede crystallization. Glass fibers may have a round cross-section or a non-circular cross-section (so called “flat glass fibers”), including oval, elliptical or rectangular. The glass fibers may be added as endless fibers or as chopped glass fibers, whereas chopped glass fibers are preferred. The glass fibers have generally a diameter of 5 to 20 μm preferably of 5 to 15 μm and more preferably of 5 to 10 μm.

According to an embodiment, the composition (C) comprises E-glass fibers.

According to another embodiment, the composition (C) comprises high modulus glass fibers having an elastic modulus (also called tensile modulus of elasticity) of at least 76, preferably at least 78, more preferably at least 80, and most preferably at least 82 GPa as measured according to ASTM D2343.

According to an embodiment, the composition (C) comprises high modulus glass fibers selected from the group consisting of R, S and T glass fibers. They are notably described in Fiberglass and Glass Technology, Wallenberger, Frederick T.; Bingham, Paul A. (Eds.), 2010, XIV. R, S and T glass fibers are composed essentially of oxides of silicon, aluminium and magnesium. In particular, R, S and T glass fibers comprise typically from 62-75 wt. % of SiO₂, from 16-28 wt. % of Al₂O₃ and from 5-14 wt. % of MgO. Additionally, R, S and T glass fibers generally comprise less than 10 wt. % of CaO.

The composition (C) may comprise glass fibers in an amount of at least 1 wt. %, for example at least 3 wt. %, at least 5 wt. %, at least 8 wt. %, at least 10 wt. %, at least 12 wt. %, or at least 15 wt. %, based on the total weight of the composition (C).

The polymer composition (C1) may comprise glass fibers in an amount of less than 50 wt. %, for example less than 40 wt. %, less than 30 wt. %, less than 25 wt. %, less than 20 wt. %, less than 18 wt. %, or less than 17 wt. %, based on the total weight of the polymer composition (C1).

Preferably, the polymer composition (C1) may comprise glass fibers in an amount ranging from 1 to 50 wt. %, for example from 2 to 38 wt. %, from 4 to 28 wt. % or from 5 to 22 wt. %, based on the total weight of the polymer composition (C1).

According to one embodiment, the composition (C) comprises:
a polymeric component comprising:
   a) from 57 to 85 wt. % or from 60 to 80 wt. % of at least one poly(aryl ether ketone) (PAEK), and
   b) from 15 to 43 wt. % or from 20 to 40 wt. % of at least one poly(aryl ether sulfone) (PAES),
   based on the total weight of the polymeric component, and
from 0 to 50 wt. % of glass fibers and/or at least one additional component, for example selected from the group consisting of fillers, colorants, lubricants, plasticizers, flame retardants, nucleating agents and stabilizers, based on the total weight of the composition (C).

According to another embodiment, the composition (C) consists essentially of:
a polymeric component comprising:
   a) from 55 to 95 wt. %, from 57 to 85 wt. % or from 60 to 80 wt. % of at least one poly(aryl ether ketone) (PAEK), and
   b) from 5 to 45 wt. %, from 15 to 43 wt. % or from 20 to 40 wt. % of at least one poly(aryl ether sulfone) (PAES),
   based on the total weight of the polymeric component, and
from 0 to 50 wt. %, from 0.1 to 35 wt. % or from 0.5 to 25 wt. % of glass fibers and/or at least one additional component selected from the group consisting of fillers, colorants, lubricants, plasticizers, flame retardant, nucleating agent and stabilizers, based on the total weight of the composition (C).

### Poly(Aryl Ether Ketone) (PAEK)

As used herein, a “poly(aryl ether ketone) (PAEK)” denotes any polymer comprising at least 50 mol. % of recurring units (R_{PAEK}) comprising a Ar′—C(═O)—Ar* group, where Ar′ and Ar*, equal to or different from each other, are aromatic groups, the mol. % being based on the total number of moles in the polymer. The recurring units (R_{PAEK}) are selected from the group consisting of units of formulae (J-A) to (J-D) below:

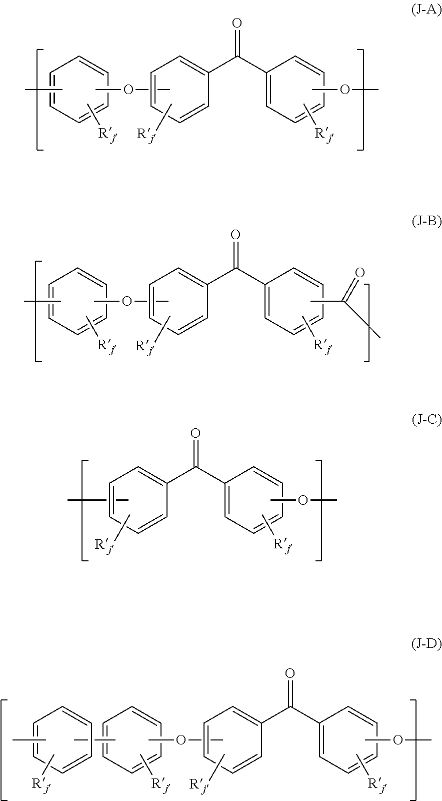

where
R′, at each location, is independently selected from the group consisting of halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium; and
j′, for each R′, is independently zero or an integer ranging from 1 to 4.

Each phenylene moiety of the recurring unit (R_{PAEK}) may, independently from one another, have a 1,2-, a 1,3- or a 1,4-linkage to the other phenylene moieties. According to an embodiment, each phenylene moiety of the recurring unit (R_{PAEK}), independently from one another, has a 1,3- or a 1,4-linkage to the other phenylene moieties. According to another embodiment yet, each phenylene moiety of the recurring unit (R_{PAEK}) has a 1,4-linkage to the other phenylene moieties.

According to an embodiment, j′ is zero for each R′. In other words, according to this embodiment, the recurring units (R_{PAEK}) are selected from the group consisting of units of formulae (J′-A) to (J′-D):

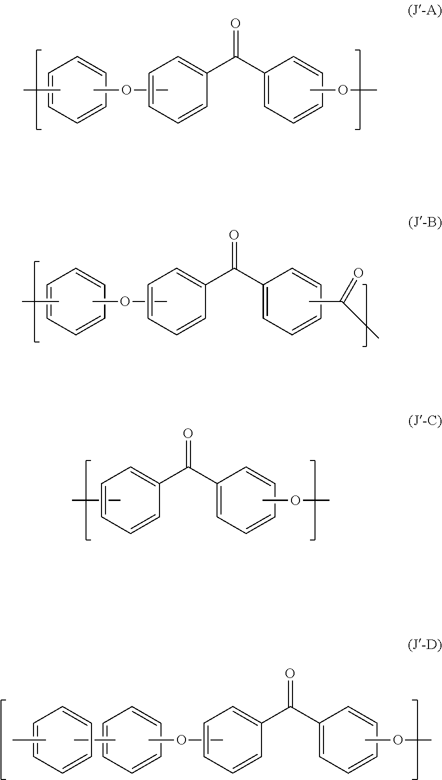

According to an embodiment of the present invention, at least 60 mol. %, at least 70 mol. %, at least 80 mol. %, at least 90 mol. %, at least 95 mol. %, at least 99 mol. % or all of the recurring units in the PAEK are recurring units (R_{PAEK}) selected from the group consisting of units of formulae (J-A) to (J-D) or selected from the group consisting of units of formulae (J′-A) to (J′-D).

In some embodiments, the PAEK is a poly(ether ether ketone) (PEEK). As used herein, a “poly(ether ether ketone) (PEEK)” denotes any polymer comprising at least 50 mol. % of recurring units of formula (J″-A), the mol. % being based on the total number of moles in the polymer:

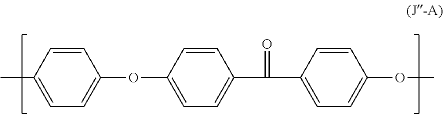

According to an embodiment, at least 60 mol. %, at least 70 mol. %, at least 80 mol. %, at least 90 mol. %, at least 95 mol. %, at least 99 mol. %, or 100 mol. % of the recurring units (R_{PAEK}) are recurring units (J″-A).

In another embodiment, the PAEK is a poly(ether ketone ketone) (PEKK). As used herein, a “poly(ether ketone ketone) (PEKK)” denotes any polymer comprising at least 50 mol. % of recurring units (R_{PAEK}) consisting in a combination of recurring units of formula (J″-B) and formula (J′″-B), the mol. % being based on the total number of moles in the polymer:

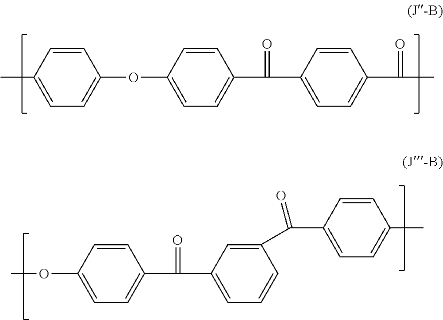

According to an embodiment, at least 60 mol. %, at least 70 mol. %, at least 80 mol. %, at least 90 mol. %, at least 95 mol. %, at least 99 mol. %, or 100 mol. % of the recurring units (R_{PAEK}) consist in a combination of recurring units (J″-B) and (J′″-B).

In yet another embodiment, the PAEK is a poly(ether ketone) (PEK). As used herein, a “poly(ether ketone) (PEK)” denotes any polymer comprising at least 50 mol. % of recurring units of formula (J″-C), the mol. % being based on the total number of moles in the polymer:

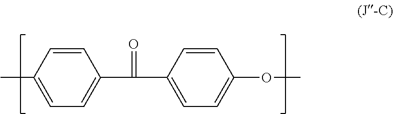

According to an embodiment, at least 60 mol. %, at least 70 mol. %, at least 80 mol. %, at least 90 mol. %, at least 95 mol. %, at least 99 mol. %, or 100 mol. % of the recurring units (R_{PAEK}) are recurring units (J″-C).

According to a preferred embodiment, the PAEK is PEEK. PEEK is commercially available as KetaSpire® PEEK from Solvay Specialty Polymers USA, LLC.

PEEK can be prepared by any method known in the art. It can for example result from the condensation of 4,4′-difluorobenzophenone and hydroquinone in presence of a base. The reactor of monomer units takes place through a nucleophilic aromatic substitution. The molecular weight (for example the weight average molecular weight Mw) can be adjusting the monomers molar ratio and measuring the yield of polymerisation (e.g. measure of the torque of the impeller that stirs the reaction mixture).

According to an embodiment of the present invention, the polymeric component of the composition (C) comprises from 55 to 95 wt. % of at least one poly(aryl ether ketone) (PAEK), for example from 55 to 95 wt. % of poly(ether ether ketone) (PEEK). The polymeric component of the composition (C) may for example comprise from 56 to 90 wt. %, from 57 to 85 wt. %, from 60 to 80 wt. %, of at least one poly(aryl ether ketone) (PAEK), based on the total weight of the polymeric component of the composition (C).

The PAEK may for example have a weight average molecular weight (Mw) ranging from 75,000 to 150,000 g/mol, for example from 82,000 to 140,000 g/mol or from 85,000 to 130,000 g/mol (as determined by gel permeation chromatography (GPC) using phenol and trichlorobenzene (1:1) at 160° C., with polystyrene standards).

The weight average molecular weight (Mw) of PAEK, for example PEEK, can be determined by gel permeation chromatography (GPC) using phenol and trichlorobenzene (1:1) at 160° C. (2×PL Gel mixed B, 10 m, 300×7.5 mm using a Polymer Laboratories PL-220 unit; flow rate: 1.0 mL/min; injection volume: 200 μL of a 0.2 w/v % sample solution), with polystyrene standards.

More precisely, the weight average molecular weight (Mw) can be measured by gel permeation chromatography (GPC). According to the method used in the experimental part, samples were dissolved in a 1:1 mixture of phenol and 1,2,4-trichlorobenzene at 190° C. temperature.

Samples were then passed through 2×PL Gel mixed B, 10 m, 300×7.5 mm using a Polymer Laboratories PL-220 unit maintained at 160° C. equipped with a differential refractive index detector and calibrated with 12 narrow molecular weight polystyrene standards (Peak molecular weight range: 1,000-1,000,000). A flow rate of 1.0 mL/min and injection volume of 200 μL of a 0.2 w/v % sample solution was selected. The weight average molecular weight (Mw) was reported.

### Poly(Aryl Ether Sulfone) (PAES)

For the purpose of the present invention, a “poly(aryl ether sulfone) (PAES)” denotes any polymer comprising at least 50 mol. % of recurring units (R_{PAES}) of formula (K), the mol. % being based on the total number of moles in the polymer:

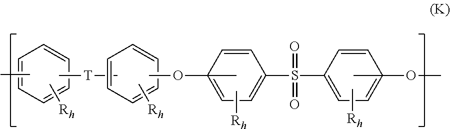

where
R, at each location, is independently selected from a halogen, an alkyl, an alkenyl, an alkynyl, an aryl, an ether, a thioether, a carboxylic acid, an ester, an amide, an imide, an alkali or alkaline earth metal sulfonate, an alkyl sulfonate, an alkali or alkaline earth metal phosphonate, an alkyl phosphonate, an amine, and a quaternary ammonium;
h, for each R, is independently zero or an integer ranging from 1 to 4; and
T is selected from the group consisting of a bond, —CH₂—, —O—, —SO₂—, —S—, —C(O)—, —C(CH₃)₂—, —C(CF₃)₂—, —C(═CCl₂)—, —C(CH₃)(CH₂CH₂COOH)—, —N═N—, —C(R′)(R″)—, —R′C═CR″—, —(CH₂)ₘ—, —(CF₂)ₘ—, an aliphatic, linear or branched divalent group, having 1-6 carbon atoms, and combinations thereof
R′ and R″, equal to or different from each other, are selected from a hydrogen, a halogen, an alkyl, an alkenyl, an alkynyl, an ether, a thioether, a carboxylic acid, an ester, an amide, an imide, an alkali or alkaline earth metal sulfonate, an alkyl sulfonate, an alkali or alkaline earth metal phosphonate, an alkyl phosphonate, an amine, and a quaternary ammonium, and m is an integer from 1 to 6.

According to an embodiment, Rj and Rk are methyl groups.

According to an embodiment, h is zero for each R. In other words, according to this embodiment, the recurring units (R_{PAES}) are units of formula (K′):

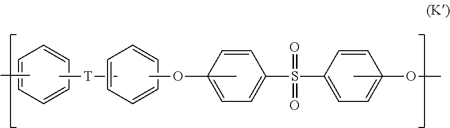

According to an embodiment of the present invention, at least 60 mol. %, at least 70 mol. %, at least 80 mol. %, at least 90 mol. %, at least 95 mol. %, at least 99 mol. % or all of the recurring units in the PAES are recurring units (R_{PAES}) of formula (K) or formula (K′).

According to an embodiment, the poly(aryl ether sulfone) (PAES) is a poly(biphenyl ether sulfone) (PPSU).

A poly(biphenyl ether sulfone) polymer is a polyarylene ether sulfone which comprises a biphenyl moiety. Poly(biphenyl ether sulfone) is also known as polyphenyl sulfone (PPSU) and for example results from the condensation of 4,4′-dihydroxybiphenyl (biphenol) and 4,4′-dichlorodiphenyl sulfone.

For the purpose of the present invention, a poly(biphenyl ether sulfone) (PPSU) denotes any polymer comprising at least 50 mol. % of recurring units (R_{PPSU}) of formula (L):

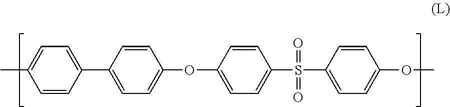

(the mol. % being based on the total number of moles in the polymer).

The PPSU polymer of the present invention can therefore be a homopolymer or a copolymer. If it is a copolymer, it can be a random, alternate or block copolymer.

According to an embodiment of the present invention, at least 60 mol. %, at least 70 mol. %, at least 80 mol. %, at least 90 mol. %, at least 95 mol. %, at least 99 mol. % or all of the recurring units in the PPSU are recurring units (R_{PPSU}) of formula (L).

When the poly(biphenyl ether sulfone) (PPSU) is a copolymer, it can be made of recurring units (R_{*PPSU}), different from recurring units (R_{PPSU}), such as recurring units of formula (M), (N) and/or (O):

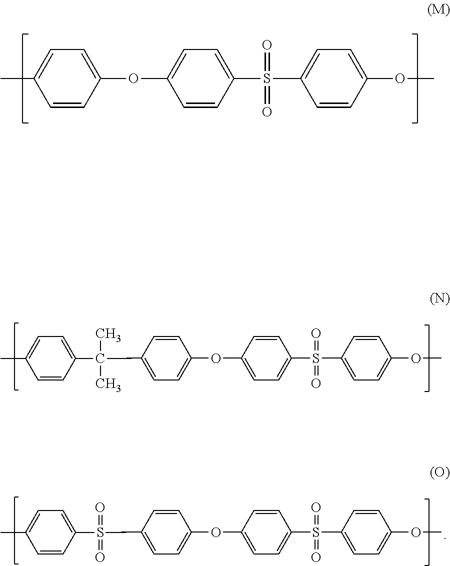

The poly(biphenyl ether sulfone) (PPSU) can also be a blend of a PPSU homopolymer and at least one PPSU copolymer as described above.

The poly(biphenyl ether sulfone) (PPSU) can be prepared by any method known in the art. It can for example result from the condensation of 4,4′-dihydroxybiphenyl (biphenol) and 4,4′-dichlorodiphenyl sulfone. The reaction of monomer units takes place through nucleophilic aromatic substitution with the elimination of one unit of hydrogen halide as leaving group. It is to be noted however that the structure of the resulting poly(biphenyl ether sulfone) does not depend on the nature of the leaving group.

PPSU is commercially available as Radel® PPSU from Solvay Specialty Polymers USA, L.L.C.

According to the present invention, the polymeric component of the composition (C) may comprise from 5 to 45 wt. % of at least one poly(aryl ether sulfone) (PAES), for example from 5 to 45 wt. % of at least one poly(biphenyl ether sulfone) (PPSU).

According to one embodiment, the polymeric component of the composition (C) comprises from 15 to 43 wt. % or from 20 to 40 wt. %, of at least one poly(biphenyl ether sulfone) (PPSU), based on the total weight of the polymeric component of the composition (C).

According to the present invention, the weight average molecular weight Mw of the PPSU may be from 30,000 to 80,000 g/mol, for example from 35,000 to 75,000 g/mol or from 40,000 to 70,000 g/mol.

The weight average molecular weight (Mw) of PPSU can be determined by gel permeation chromatography (GPC) using methylene chloride as a mobile phase, with polystyrene standards.

According to an embodiment, the poly(aryl ether sulfone) (PAES) is a polyether sulfone (PES).

As used herein, a polyethersulfone (PES) denotes any polymer comprising at least 50 mol. % recurring units (R_{PES}) of formula (O), the mol. % being based on the total number of moles of recurring units in the polymer:

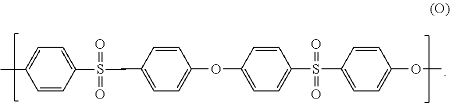

The PES polymer of the present invention can therefore be a homopolymer or a copolymer. If it is a copolymer, it can be a random, alternate or block copolymer.

According to an embodiment of the present invention, at least 60 mol. %, at least 70 mol. %, at least 80 mol. %, at least 90 mol. %, at least 95 mol. %, at least 99 mol. % or all of the recurring units in the PES are recurring units (R_{PSU}) of formula (N).

When the polysulfone (PES) is a copolymer, it can be made of recurring units (R*_{PES}), different from recurring units (R_{PES}), such as recurring units of formula (L), (M) and/or (N) above described.

PES can be prepared by known methods and is notably available as VERADEL® PESU from Solvay Specialty Polymers USA, L.L.C.

According to an embodiment, the poly(aryl ether sulfone) (PAES) is a polysulfone (PSU).

For the purpose of the present invention, a polysulfone (PSU) denotes any polymer comprising at least 50 mol. % of recurring units (R_{PSU}) of formula (N):

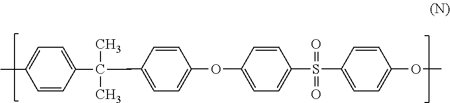

(the mol. % being based on the total number of moles in the polymer).

The PSU polymer of the present invention can therefore be a homopolymer or a copolymer. If it is a copolymer, it can be a random, alternate or block copolymer.

According to an embodiment of the present invention, at least 60 mol. %, at least 70 mol. %, at least 80 mol. %, at least 90 mol. %, at least 95 mol. %, at least 99 mol. % or all of the recurring units in the PSU are recurring units (R_{PSU}) of formula (N).

When the polysulfone (PSU) is a copolymer, it can be made of recurring units (R*_{PSU}), different from recurring units (R_{PSU}), such as recurring units of formula (L), (M) and/or (0) above described.

PSU is available as Udel® PSU from Solvay Specialty Polymers USA, L.L.C.

According to the present invention, the polymeric component of the composition (C) may comprise from 5 to 45 wt. % of a poly(aryl ether sulfone) (PAES), for example from 5 to 45 wt. % of a polysulfone (PSU) or a polyethersulfone (PES).

According to one embodiment, the polymeric component of the composition (C) comprises from 15 to 43 wt. % or from 20 to 40 wt. %, of polysulfone (PSU) or a polyethersulfone (PES), based on the total weight of the polymeric component of the part material.

According to the present invention, the weight average molecular weight Mw of the PSU may be from 30,000 to 80,000 g/mol, for example from 35,000 to 75,000 g/mol or from 40,000 to 70,000 g/mol.

The weight average molecular weight (Mw) of PAES, for example PPSU, PES and PSU, can be determined by gel permeation chromatography (GPC) using methylene chloride as a mobile phase (2×5μ mixed D columns with guard column from Agilent Technologies; flow rate: 1.5 mL/min; injection volume: 20 μL of a 0.2 w/v % sample solution), with polystyrene standards.

More precisely, the weight average molecular weight (Mw) can be measured by gel permeation chromatography (GPC), using methylene chloride as the mobile phase. In the experimental part, the following method was used: two 5μ mixed D columns with guard column from Agilent Technologies were used for separation. An ultraviolet detector of 254 nm was used to obtain the chromatogram. A flow rate of 1.5 ml/min and injection volume of 20 μL of a 0.2 w/v % solution in mobile phase was selected. Calibration was performed with 12 narrow molecular weight polystyrene standards (Peak molecular weight range: 371,000 to 580 g/mol). The weight average molecular weight (Mw) was reported.

### Metallic Coating

The present invention relates to an article or a part, comprising at least one coating (2) of metal having a thickness of at least 20 μm, preferably at least 30 μm, and more preferably at least 40 μm.

As used herein, the term “coating of metal”, “metallic coating” or “metallic layer” means a metallic deposit/layer applied to part of or the entire exposed surface of an article. The metallic coating is intended to adhere to the surface of the polymer substrate to provide mechanical strength, wear resistance, aesthetic appeal, anti-microbial properties and a low coefficient of friction.

The coating of metal may be fine-grained and/or coarse-grained. As used herein, the term “fine-grained” means average grain-size ranging from 2 nm to 5,000 nm. As used herein, the term “coarse-grained” means average grain-size above 5,000 nm.

The article or a part of the present invention may comprise several metallic coatings of different thicknesses and compositions. For example, it may comprise a metallic coating having a thickness of at least 20 μm and an additional coating having a thickness of less than 20 μm, for example less than 10 μm. As another example, it may comprise a coarse-grained metallic coating having a thickness of at least 40 μm and an additional fine-grained coating having a thickness of less than 20 μm, for example less than 10 μm.

The grain size can be uniform throughout the deposit; alternatively, it can consist of layers with different microstructure/grain size. Layering and/or grading the metallic layer by changing the composition, grain size or any other physical or chemical property is within the scope of this invention as well.

According to the present invention, the entire polymer surface can be coated; alternatively, metal patches or sections can be formed on selected areas only (e.g. without the need to coat the entire article).

The coating of metal is preferably be substantially porosity-free.

According to an embodiment, the coating of metal has a minimal thickness of at least 20 μm, preferably at least 30 μm, even more preferably at least 40 μm.

According to an embodiment, the coating of metal has a maximum thickness of 50 mm, preferably 40 mm, or even more preferably 30 or 20 mm.

Articles and parts of the present disclosure comprise a single or several metallic layers applied to the first layer (1) of a composition (C) as well as multi-layer laminates composed of alternating layers of metallic layers, which can for example be fine-grained and/or coarse-grained.

According to an embodiment, the composition of the metal coating comprises at least one metal selected from the group consisting of Ag, Al, Au, Co, Cr, Cu, Fe, Ni, Mn, Mo, Pb, Pd, Pt, Rh, Ru, Sn, Ti, W, Zn, Zr and combinations thereof.

Optional components can be added to the composition of the metal coating as follows:
metals: Ag, Al, In, Mg, Si, Sn, Pt, Ti, V, W, Zn;
metal oxides: Ag₂O, Al₂O₃, SiO₂, SnO₂, TiO₂, ZnO;
carbides of B, Cr, Bi, Si, W;
carbon: carbon nanotubes, diamond, graphite, graphite fibers);
glass;
glass fibers; and
polymer materials: PTFE, PVC, PE, PP, epoxy resins.

According to a preferred embodiment, the metal is selected from the group consisting of Al and Ti.

### Optional Additional Layers

The article or part of the present invention may comprise one or several layers: an etching layer, an anodized layer, a die coloring layer, a top layer . . . etc.

According to an embodiment, the article or part comprise an anodized layer (3) and/or a top layer (4).

### Methods of Making the Composition (C)

Exemplary embodiments also include methods of making the composition (C).

The composition (C) can be made by methods well-known to the person of skill in the art. For example, such methods include, but are not limited to, melt-mixing processes. Melt-mixing processes are typically carried out by heating the polymer components above the melting temperature of the thermoplastic polymers thereby forming a melt of the thermoplastic polymers. In some embodiments, the processing temperature ranges from about 280-450° C., preferably from about 290-440° C., from about 300-430° C. or from about 310-420° C. Suitable melt-mixing apparatus are, for example, kneaders, Banbury mixers, single-screw extruders, and twin-screw extruders. Preferably, use is made of an extruder fitted with means for dosing all the desired components to the extruder, either to the extruder's throat or to the melt. In the process for the preparation of the layer (1), the components of the composition (C), e.g. the PAES, the PAEK, and the additional components, for example the glass fibers, are fed to the melt-mixing apparatus and melt-mixed in that apparatus. The components may be fed simultaneously as a powder mixture or granule mixer, also known as dry-blend, or may be fed separately.

The order of combining the components during melt-mixing is not particularly limited. In one embodiment, the component can be mixed in a single batch, such that the desired amounts of each component are added together and subsequently mixed. In other embodiments, a first sub-set of components can be initially mixed together and one or more of the remaining components can be added to the mixture for further mixing. For clarity, the total desired amount of each component does not have to be mixed as a single quantity. For example, for one or more of the components, a partial quantity can be initially added and mixed and, subsequently, some or all of the remainder can be added and mixed.

Methods of Coating the Composition (C) with a Metal, Methods for Preparing the Part/Article

Another aspect of the invention is a process for preparing the article/part of the present invention, by metallisation of an article/part comprising a first layer of a composition (C) which comprises a polymeric component comprising at least one PAEK polymer and at least one PAES polymer, wherein the composition (C) has a melting temperature (Tm) of at least 290° C., as measured by differential scanning calorimetry (DSC) according to ASTM D3418.

The metallic coating can be produced by direct current DC or pulse electrodeposition, electroless deposition, physical vapor deposition (PVD), chemical vapor deposition (CVD) and gas condensation or the like.

The person skilled in the art of plating knows how to electroplate or electroless plate selected metals, alloys or metal matrix composites choosing suitable plating bath formulations and plating conditions. Similarly, the person skilled in the art of PVD, CVD and gas condensation techniques knows how to prepare metal, alloy or metal matrix composite coatings.

According to an embodiment, the metallisation is performed by physical vapor deposition (PVD) in a high vaccum environment using thermal evaporation equipment.

According to an embodiment, the article/part is heated a processing temperature (Tp) ranging from 250 to 340° C. before metal deposition for example from 260 to 330° C. or from 270 to 320° C.

The surface of the polymer composition (C) may be etched prior to metallization, in order to increase the roughness of the surfaces, change the surface chemical constitution, degrade or dissolve low molecular weights which migrate to the surface, and relieve residual surface stresses. The adhesion and durability of the metallic coating can notably be improved by the condition of the surface of the composition (C).

According to an embodiment, the article/part is etched (or milled) using a chemical solution before metal deposition. With the chemical etching or milling, part of the composition (C) is removed from the surface of the part/article by treatment thereof to obtain a part/article having a desired structural or ornamental configuration. The chemical etching solution may comprise sulfuric acid, for example a mixture of sulfuric acid and at least one carboxylic acid, for example phosphoric acid and/or nitric acid, as described in U.S. Pat. No. 5,160,600. Chromic acid etching solutions may also be used, as described, for example, in U.S. Pat. Nos. 4,610,895, 6,645,557 and 3,445,350. Permanganate solutions (e.g. hot alkaline permanganate solution that also contains a material, such as sodium hypochlorite; alkaline permanganate solution comprising potassium permanganate and sodium hydroxide, solution that comprises water, permanganate ions, and manganate ions) may also be used, as described for example in U.S. Pat. Nos. 3,625,758, 4,042,729, 5,648,125, and 4,948,630. An electrolyte comprising manganese(III) ions in a solution of 9 to 15 molar sulfuric acid or phosphoric acid may also be used, as described in U.S. patent application 2013/0186774 A1.

According to an embodiment, the article/part is anodized after metal deposition. Anodizing is accomplished by immersing the mettalized part/article into an acid electrolyte bath and passing an electric current through the medium. A cathode is mounted to the inside of the anodizing tank; the metal, e.g. aluminium, acts as an anode, so that oxygen ions are released from the electrolyte to combine with the metal atoms, e.g. Al, at the surface of the part being anodized.

According to an embodiment, the article/part is polished before or after metal deposition.

According to an embodiment, the article/part is colored before or after metal deposition.

### Applications

The articles and parts can be employed in a very wide variety of industrial sectors in which metallic surfaces are required, for example in the automotive industry, for instance for surrounds of display instruments, radios, door handles, and for window levers, heating grilles, dashboard buttons, headlamp reflectors, rear lights, etc., and also in the radio, TV and electronics industry, especially for printed circuits, and also in multilayer and hybrid circuits, and as chip supports, and in EMI shielding installations, etc.; they are used, moreover, in the aircraft industry, in dentistry and medicine, in the optics industry, for example in the production of mirrors, and in household articles and electrical appliances.

The articles and parts are preferably employed in electrical & electronic applications, mobile electronics, smart devices & wearables and smart phones.

Should the disclosure of any patents, patent applications, and publications which are incorporated herein by reference conflict with the description of the present application to the extent that it may render a term unclear, the present description shall take precedence.

1-14. (canceled)

15. An article or a part, comprising:
a first layer (1) of a composition (C) comprising a polymeric component comprising
a) at least one poly(aryl ether ketone) polymer (PAEK),
b) at least one poly(aryl ether sulfone) polymer (PAES),
wherein the composition further comprises glass fibers and/or carbon fibers,
wherein the composition (C) has a melting temperature (Tm) of at least 290° C., as measured by differential scanning calorimetry (DSC) according to ASTM D3418, and
at least one coating (2) of metal having a thickness of at least 20 μm.

16. The article or part of claim 15, wherein the polymeric component comprises:
a) from 55 to 95 wt. % of at least one PAEK, and
b) from 5 to 45 wt. % of at least one PAES,
based on the total weight of the polymeric component in the composition (C).

17. The article or part of claim 15, wherein the PAES is a poly(biphenyl ether sulfone) (PPSU), a polyethersulfone (PES) and/or a polysulfone (PSU).

18. The article or part of claim 15, wherein the composition (C) also comprises from 0.5 wt. % to 50 wt. % of glass fibers and/or carbon fibers.

19. The article or part of claim 15, wherein the metal is selected from the group consisting of Al and Ti.

20. The article or part of claim 15, further comprising an anodized layer (3) and/or a top layer (4).

21. A process for preparing the article or part of claim 15, the process comprising metallisation of an article or part comprising a first layer of a composition (C) which comprises a polymeric component comprising at least one poly(aryl ether ketone) polymer (PAEK), wherein the composition (C) has a melting temperature (Tm) of at least 290° C., as measured by differential scanning calorimetry (DSC) according to ASTM D3418.

22. The process of claim 21, wherein the metallisation is performed by physical vapor deposition (PVD) in a high vaccum environment using thermal evaporation equipment.

23. The process of claim 21, wherein the article or part is heated a processing temperature (Tp) ranging from 250 to 340° C. before metal deposition.

24. The process of claim 21, wherein the article or part is etched using a chemical solution before metal deposition.

25. The process of claim 21, wherein the article or part is polished before or after metal deposition.

26. The process of claim 21, wherein the article or part is colored before or after metal deposition.

27. The process of claim 21, wherein the article or part is anodized after metal deposition.

28. Use of the article or part produced by the method of claim 21, for electrical & electronic applications, mobile electronics, smart devices & wearables and smart phones.
